(19) United States
(12) Patent Application Publication
(10) Pub. No.: US 2018/0279505 A1
(43) Pub. Date: Sep. 27, 2018

(54) MOTOR DRIVE DEVICE

(71) Applicant: FANUC CORPORATION, Yamanashi (JP)

(72) Inventors: Hironao TANOUCHI, Yamanashi (JP); Naoki MASUDA, Yamanashi (JP)

(73) Assignee: FANUC CORPORATION, Yamanashi (JP)

(21) Appl. No.: 15/920,623

(22) Filed: Mar. 14, 2018

(30) Foreign Application Priority Data
Mar. 24, 2017 (JP) 2017-059588

(51) Int. Cl. H05K 7/20; H05K 1/02; F28F 3/02; F28F 13/06

(52) U.S. Cl. CPC H05K 7/20154; H05K 1/0203; F28F 13/06; F28F 3/02; H05K 7/20145

(57) ABSTRACT

The present invention has an object of providing a motor drive device provided with a cooling mechanism by way of a fan motor, which is capable of also cooling separate elements in the surroundings of a heat generating element due to further improving the cooling function. The motor drive device is equipped with a fan motor, and a heat sink which cools the heat generating element on a printed substrate by way of exchanging heat with the heat generating element, in which the heat sink includes a main body of cylindrical shape fixed to the heat generating element, and having an air duct through which cooling airflow flows, and a communication hole that communicates from an exposed outer circumferential face of the main body to the air duct, and in which the fan motor generates cooling airflow that flows through the air duct.

This application is based on and claims the benefit of priority from Japanese Patent Application No. 2017-059588, filed on 24 Mar. 2017, the content of which is incorporated herein by reference.

### BACKGROUND OF THE INVENTION

### Field of the Invention

The present invention relates to a motor drive device provided with a cooling mechanism by way of a fan motor.

### Related Art

Conventionally, a motor drive device that includes a fan motor and a heat sink for cooling an element which generates heat installed on a printed substrate (hereinafter referred to as heat generating element) has been known. The heat sink is mounted to be arranged adjacently to the heat generating element via thermally conductive grease, solder or the like. The heat sink exchanges heat with the heat generating element via the thermally conductive grease, solder or the like. The heat sink exchanges heat with air, by way of being exposed to the flow of air for cooling made by the fan motor (hereinafter referred to as cooling airflow).

As a cooling structure using a heat sink and a fan motor, a device has been proposed that cools components by transferring heat to the heat sink from an element having great heat generation using a heat pipe and an absorber plate (e.g., refer to Patent Document 1). In addition, a device has been proposed that efficiently cools an element having great heat generation by combining the fan motor and the heat sink which partially forms a duct shape (e.g., refer to Patent Document 2).

Patent Document 1: Japanese Unexamined Patent Application, Publication No. H11-87956

Patent Document 2: Japanese Unexamined Patent Application, Publication No. 2007-5600

### SUMMARY OF THE INVENTION

With the device disclosed in Patent Document 1, the absorber plate is installed to the heat generating element. The heat pipe is coupled to the absorber plate. Then, the heat pipe is installed to the heat sink. In addition, with the device disclosed in Patent Document 2, the airflow made by the fan motor is made to flow in the duct of the heat sink. Both devices described in Patent Document 1 and Patent Document 2 can cool a heat generating element.

On the other hand, it is common for another element which is susceptible to heat in the surrounding of the heat generating element, or another element that generates heat itself (e.g., electrolytic capacitor, etc.) to be provided. If leaving the heat of such another element to stand, cases linked to thermal runaway, rise in deterioration rate, damage to elements, etc. are possible

Therefore, if it is possible to also cool the other elements in the surrounding of the heat generating element, it is very useful.

The present invention has an object of providing a motor drive device provided with a cooling mechanism by way of a fan motor, the motor drive device being capable of cooling other elements in the surrounding of a heat generating element by way of further raising the cooling function.

A first aspect of the present invention relates to a motor drive device (e.g., the motor drive device 1 described later) including: a heat sink (e.g., the heat sink 40 described later) that cools a heat generating element (e.g., the heat generating element 20 described later) on a printed substrate (e.g., the printed substrate 10 described later) by exchanging heat with the heat generating element; and a fan motor (e.g., the fan motor 50 described later), in which the heat sink includes: a main body (e.g., the main body 41 described later), of cylindrical shape, arranged adjacently to the heat generating element, and having an air duct (e.g., the air duct 43 described later) through which cooling airflow (e.g., the cooling airflow F1 described later) flows; and a communication hole (e.g., the communication hole 42 described later) that communicates from an exposed outer circumferential face of the main body to the air duct, and in which the fan motor generates cooling airflow that flows through the air duct.

According to a second aspect of the present invention, in the motor drive device as described in the first aspect, it is preferable for the communication hole to communicate from an outer circumferential face of the main body to the air duct by sloping to a downstream side of the cooling airflow.

According to a third aspect of the present invention, it is preferable for the motor drive device as described in the first or second aspect to further include a branch part (e.g., the branch part 44 described later) of cylindrical shape that projects from the outer circumferential face of the main body, and communicates with the air duct via the communication hole.

According to a fourth aspect of the present invention, in the motor drive device as described in the third aspect, it is preferable for the branch part to be a member having thermal conductivity, and to be arranged proximately to a separate element (e.g., the peripheral element 30 described later) which is arranged in a vicinity of the heat generating element.

According to the present invention, it is possible to provide a motor drive device provided with a cooling mechanism by way of a fan motor, the motor drive device being capable of cooling other elements in the surrounding of a heat generating element by way of further raising the cooling function.

### BRIEF DESCRIPTION OF THE DRAWINGS

FIG. 1 is a schematic plan view showing a motor drive device related to a first embodiment of the present invention;

FIG. 2 is a cross-sectional view along the line A-A in FIG. 1;

FIG. 3 is a schematic plan view showing a heat sink of a motor drive device according to a second embodiment;

FIG. 4 is a schematic plan view showing a motor drive device according to a third embodiment;

FIG. 5 is a schematic plan view showing a motor drive device according to a fourth embodiment; and

FIG. 6 is a schematic side view showing a modified example of the motor drive devices according to the third embodiment and fourth embodiment.

### DETAILED DESCRIPTION OF THE INVENTION

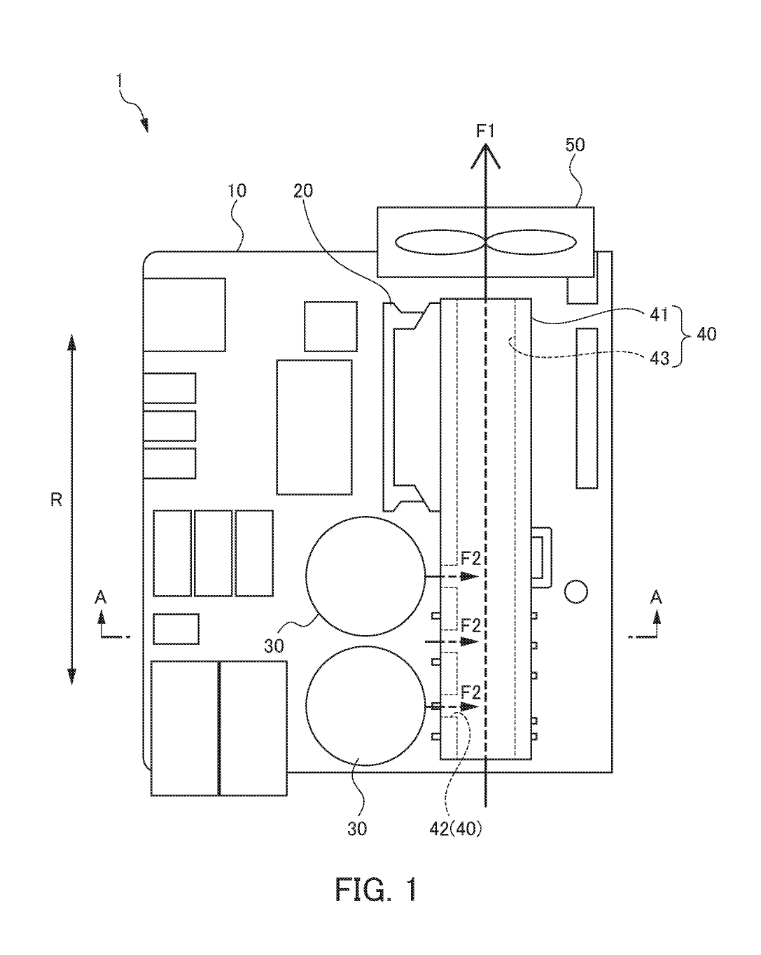

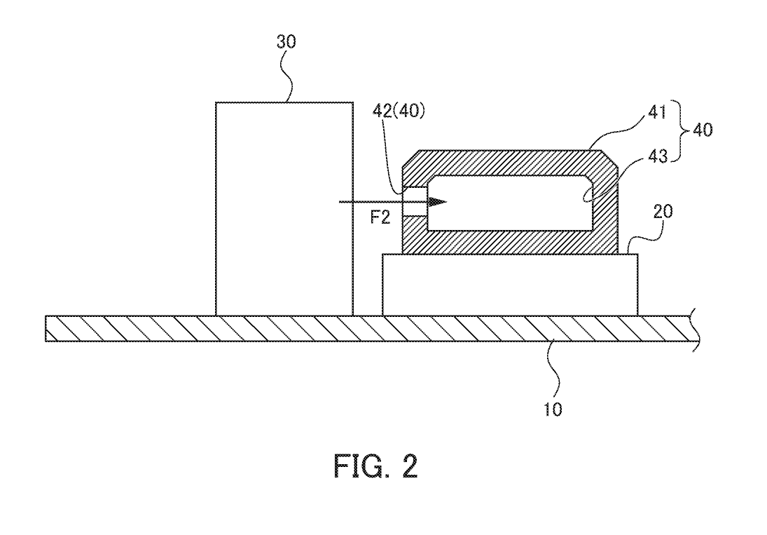

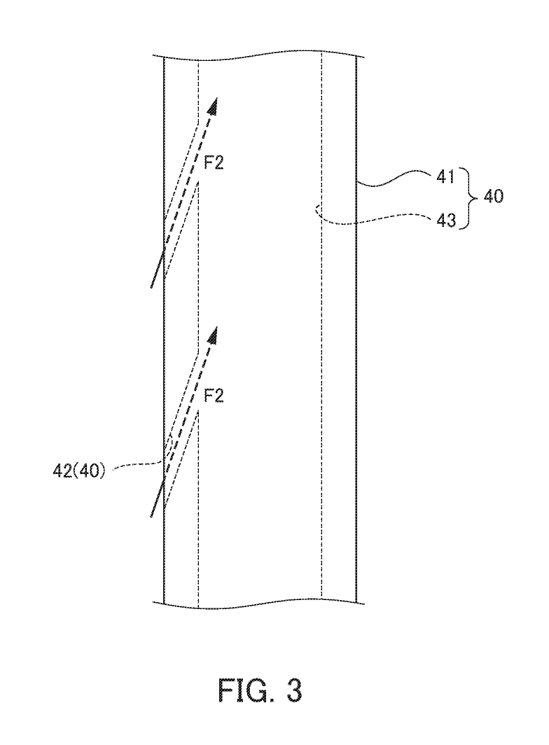

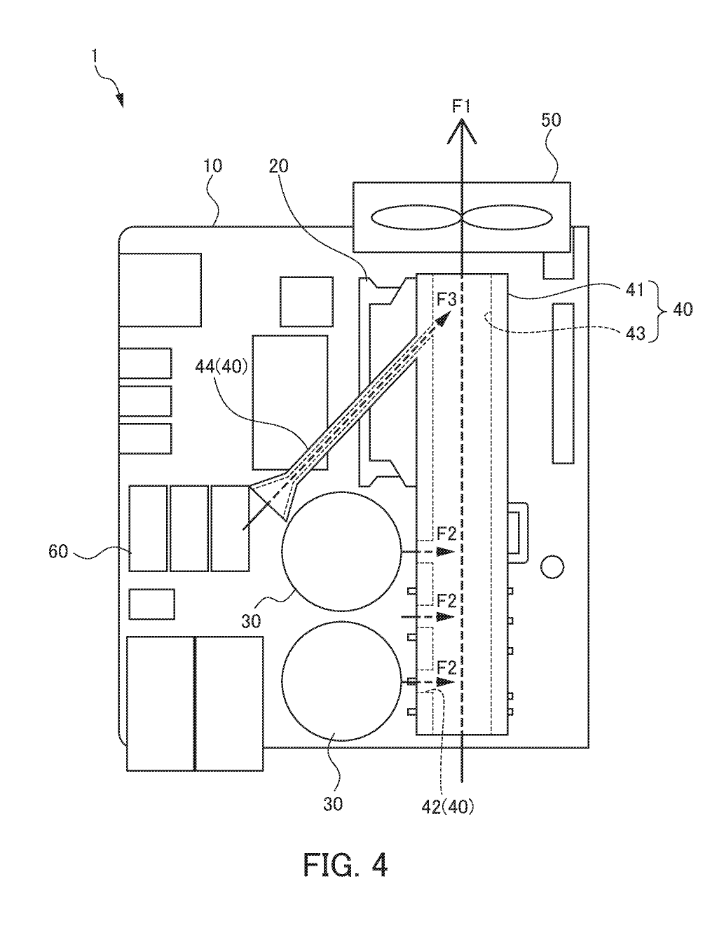

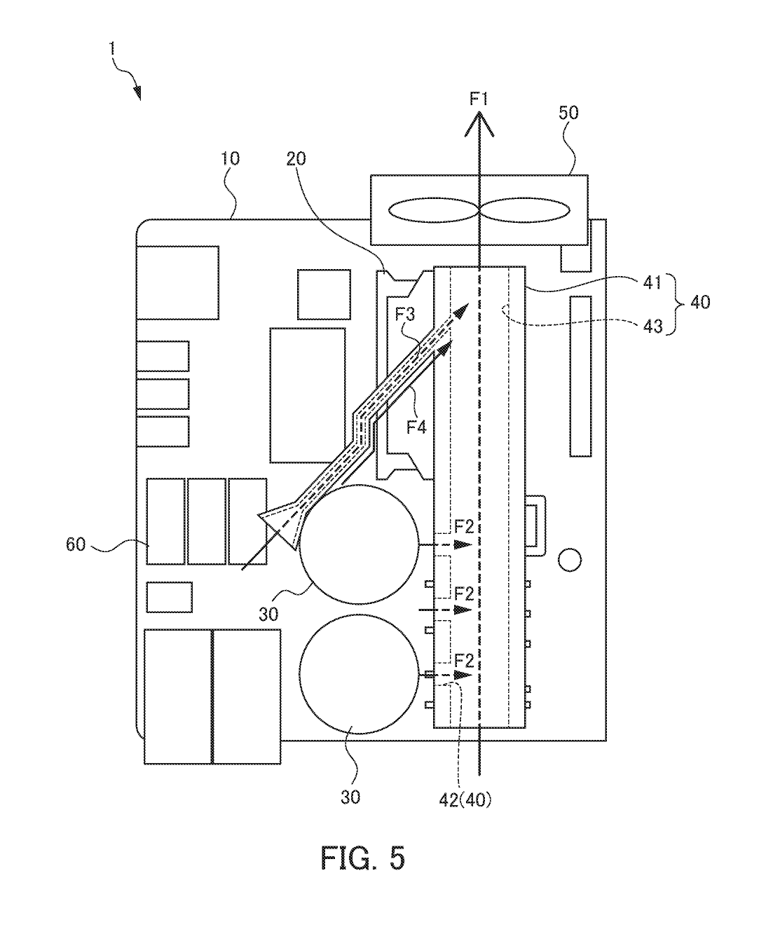

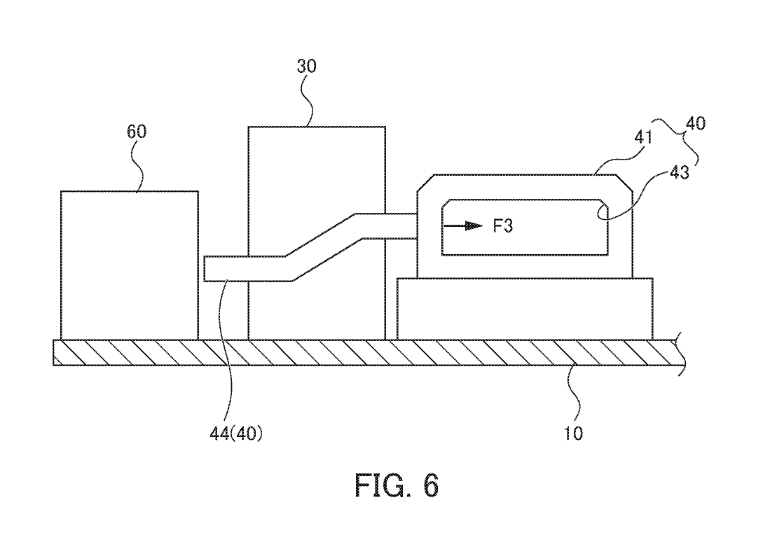

Hereinafter, a motor drive device 1 according to each embodiment of the present invention will be explained by referencing FIGS. 1 to 6. FIG. 1 is a schematic plan view showing a motor drive device 1 according to the first embodiment of the present invention. FIG. 2 is a cross-sectional view along the line A-A in FIG. 1. FIG. 3 is a schematic plan view showing a heat sink 40 of a motor drive device 1 according to the second embodiment. FIG. 4 is a schematic plan view showing a motor drive device 1 according to the third embodiment. FIG. 5 is a schematic plan view showing a motor drive device 1 according to the fourth embodiment. FIG. 6 is a schematic side view showing a modified example of the motor drive devices 1 according to the third embodiment and the fourth embodiment.

### First Embodiment

First, the motor drive device 1 according to the first embodiment will be explained by referencing FIG. 1 and FIG. 2. The motor drive device 1, for example, is a servo amplifier. The motor drive device 1 has a box-shaped housing (not illustrated). Then, the motor drive device 1 includes, inside of the housing (not illustrated), a printed substrate 10, heat generating element 20, another element arranged in the surroundings of the heat generating element 20 (hereinafter referred to as peripheral element 30), heat sink 40, and fan motor 50, as shown in FIG. 1.

The printed substrate 10 is provided inside of the housing (not illustrated). In the present embodiment, the printed substrate 10 is arranged to have the board surface run along a vertical direction R.

The heat generating element 20, for example, is a power element handling a relatively large electrical current such as an inverter. The heat generating element 20 is arranged on the printed substrate 10. The heat generating element 20 generates more abundant heat due to handling the relative large electrical current.

The peripheral element 30 is an electrolytic capacitor, for example. The peripheral element 30 is arranged on the printed substrate 10. The peripheral element 30 generates heat of a smaller amount than the heat generating element 20.

The heat sink 40 is a member that suppresses overheating of the heat generating element 20, by exchanging heat with the heat generating element 20. The heat sink 40 is arranged adjacently to the heat generating element 20. It should be noted that “arranged adjacently” indicates the matter of being arranged so as to be able to achieve the suppression function with the overheating by heat exchange as a heat sink. For example, a form is included in which the heat sink 40 and heat generating element 20 are contacting via a heat conductive material such as a thermally conductive grease (not illustrated), soldering or a heat conductive sheet, eliminating the air layer formed between both. The heat sink 40 includes a main body 41 and communication hole 42, as shown in FIG. 1.

The main body 41 is formed from metal, for example. The main body 41 is formed in a cylindrical shape, and includes an air duct 43 inside. More specifically, the main body 41 is formed in a rectangular cylindrical shape, as shown in FIG. 2. The main body 41 is arranged adjacently to the heat generating element 20. For example, one side on the outer circumferential face of the main body 41 contacts the heat generating element 20 via thermally conductive grease (not illustrated).

The air duct 43 is a channel for wind, and is demarcated by the inner circumferential face of the main body 41. The air duct 43 penetrates the main body 41 in the longitudinal direction thereof. The air duct 43 is a channel through which the cooling airflow F1 which cools the main body 41 flows, for example. The main body 41 is formed in a cross-section of a size and shape allowing the cooling airflow F1 to flow therethrough. In the present embodiment, the air duct 43 penetrates through the main body 41 along the vertical direction R.

The communication hole 42 communicates with the air duct 43 from the exposed outer circumferential face of the main body 41. In other words, the communication hole 42 is a channel for air that penetrates from the outer circumferential face of the main body 41 towards the inner circumferential face. A plurality of the communication holes 42 is provided along the air duct 43. In other words, a plurality of the communication holes 42 is provided along the vertical direction R. In addition, the communication hole 42 communicates from a face opposing the peripheral element 30, on the outer circumferential face of the main body 41, to the air duct 43. A plurality of communication holes 42 is formed in a cross-section of a size and shape allowing the cooling airflow F1 to flow therethrough. In the present embodiment, three communication holes 42 are provided as shown in FIG. 1.

The fan motor 50 is provided in order to discharge heat from the inside of the motor drive device 1, by way of creating a flow of air (cooling airflow F1) inside of the motor drive device 1 by way of the suction force thereof. The fan motor 50 is arranged adjacently to the heat sink 40. More specifically, the fan motor 50 is arranged adjacently to one opening of the air duct 43. In the present embodiment, the fan motor 50 is arranged adjacently to an opening on the upper side in the vertical direction R of the air duct 43.

Next, the cooling operation for the heat generating element 20 and peripheral element 30, using the heat sink 40 and fan motor 50, will be explained. First, the heat generating element 20 generates heat by way of operating. In addition, the peripheral element 30 generates heat by way of operating.

The heat sink 40 is heated by exchanging heat with the heat generating element 20. The fan motor 50 generates the cooling airflow F1 inside of the motor drive device 1 by way of rotating. In the present embodiment, the fan motor 50 generates the cooling airflow F1 that discharges heat upwards from the inside of the motor drive device 1 (housing not illustrated), by way of rotating. The fan motor 50 generates the cooling airflow F1 flowing through the air duct 43, by way of generating the cooling airflow F1 that discharges heat upwards.

The cooling airflow F1 flowing through the air duct 43 is flowed towards one opening from the other opening of the air duct 43. In addition, by the cooling airflow F1 being produced inside of the air duct 43, a difference in air pressure is produced between the atmosphere in the surroundings of the main body 41 and the atmosphere inside of the air duct 43 In other words, the atmosphere in the surroundings of the main body 41 becomes positive pressure. In addition, the atmosphere within the air duct 43 becomes negative pressure.

By way of the air pressure difference between the atmosphere in the surroundings of the main body 41 and the atmosphere within the air duct 43, a flow F2 of air flowing from the surroundings of the main body 41 towards the air duct 43 is produced. As a result, the peripheral element 30 which is separate from the heat generating element 20 arranged around the heat sink 40 is thereby cooled. More specifically, the peripheral element 30 in the vicinity of the opening of the communication hole 42 (opening formed in outer circumferential face of the main body 41) is cooled by the flow F2 of air.

According to the motor drive device 1 related to the above first embodiment of the present invention, the following such effects are exerted.

(1) The motor drive device 1 includes the heat sink 40 and fan motor 50. Then, the heat sink 40 includes the main body 41 of cylindrical shape which is arranged adjacently to the heat generating element 20, and has the air duct 43 through which the cooling airflow F1 flows; and the communication hole 42 which communicates from the exposed outer circumferential face of the main body 41 to the air duct 43. In addition, the fan motor 50 generates the cooling airflow F1 which flows through the air duct 43. Since the atmosphere within the air duct 43 thereby becomes negative pressure relative to the atmosphere outside of the main body 41, it is possible to create the flow F2 of air which flows from the atmosphere outside of the main body 41 through the communication hole 42 to the air duct 43. Therefore, in the motor drive device 1 provided with the cooling function by way of a fan motor, it is possible to efficiently cool not only the heat generating element 20, but also separate elements existing in the surroundings of the heat sink 40 (peripheral element 30) by way of further improving the cooling function.

### Second Embodiment

Next, the motor drive device 1 according to the second embodiment of the present invention will be explained by referencing FIG. 3. Upon explanation of the second embodiment and later, the same reference symbols will be attached for identical constituent elements, and explanations thereof will be omitted or simplified. The motor drive device 1 according to the second embodiment differs from the first embodiment in the point of the communication hole 42 communicating from the outer circumferential face of the main body 41 to the air duct 43 by sloping to the downstream side of the cooling airflow F1, as shown in FIG. 3.

Next, the cooling operation for the heat generating element 20 and peripheral element 30, using the heat sink 40 and fan motor 50, will be explained. The atmosphere in the surroundings of the main body 41 (surroundings of peripheral element 30) becomes positive pressure by way of the cooling airflow F1 flowing through the air duct 43. In addition, the atmosphere within the air duct 43 becomes negative pressure. Then, the air around the peripheral element 30 is heated by the heat produced by the peripheral element 30, and rises in the vertical direction. Since the communication hole 42 communicates from the outer circumferential face of the main body 41 to the air duct 43 by sloping to the downstream side of the cooling airflow F1 (upper side of vertical direction R in present embodiment), the flow F2 of air produced by the flow of air due to air pressure difference and the flow of air due to the convection action of air merging is formed at the surroundings of the peripheral element 30.

According to the motor drive device 1 related to the above second embodiment of the present invention, the following such effects are exerted.

(2) The communication hole 42 is formed so as to communicate from the outer circumferential face of the main body 41 to the air duct 43 by sloping to the downstream side of the cooling airflow F1. In the case of the opening of the communication hole 42 at the outer circumferential face side of the main body 41 being arranged below the opening on the side of the air duct 43, it is possible to increase the flowrate of air passing through the communication hole 42 using the convection action of air. Therefore, it is possible to more efficiently cool elements existing in the surroundings of the heat sink 40.

### Third Embodiment

Next, the motor drive device 1 according to the third embodiment of the present invention will be explained by referencing FIG. 4 and FIG. 5. The motor drive device 1 according to the third embodiment differs from the first embodiment and the second embodiment in the point of further including a branch part 44, as shown in FIG. 4. In addition, the motor drive device 1 according to the third embodiment differs from the first embodiment and the second embodiment in the point of the including a separate element (hereinafter referred to as distal element 60) which is separate from the heat generating element 20 and peripheral element 30, and which is distanced further than the peripheral element 30 from the heat sink 40.

The branch part 44 is formed in a cylindrical shape. The branch part 44 projects from the outer circumferential face of the main body 41. More specifically, the branch part 44 has one end fixed to the main body 41, and the other end is arranged in the form of a cantilever to be a free end. Then, the branch part 44 communicates with the air duct 43 via the communication hole 42. The branch part 44 has the other end side arranged proximately to the distal element 60. In the present embodiment, the branch part 44 is fixed to the main body 41 to slope to the downstream side of the cooling airflow F1 (upstream side of vertical direction R) from the other end towards the one end. In other words, the branch part 44 has one end arranged closer to the downstream side of cooling airflow F1 (upper side in vertical direction R) than the other side, and the one side is fixed to the main body 41. In addition, the branch part 44 expands in the inside diameter and outside diameter of the other end part as approaching the other edge.

Next, the cooling operation for the heat generating element 20, peripheral element 30 and distal element 60, using the heat sink 40 and fan motor 50, will be explained. The atmosphere around the main body 41 becomes positive pressure by way of the cooling airflow F1 flowing in the air duct 43. In addition, the atmosphere within the air duct 43 becomes negative pressure. In addition, the atmosphere of the inside of the branch part 44 becomes negative pressure. A flow F3 of air flowing into the other end of the branch part 44 is thereby formed around the other end of the branch part 44. Then, the inflowing air flows through the air duct 43 via the inside of the branch part 44. In addition, since the inside diameter and outside diameter of the other end part of the branch part 44 expand, a wider range of the flow F3 of air is formed compared to the case of not expanding in diameter.

According to the motor drive device 1 related to the above third embodiment of the present invention, the following such effects are exerted.

(3) The motor drive device 1 further includes the cylindrical branch part 44 which projects from the outer circumferential face of the main body 41, and communicates with the air duct 43 via the communication hole 42. Since it is thereby possible to cool other elements (distal element 60) which are at positions distanced from the heat sink 40 by way of the branched part 44, the range of elements serving as the cooling targets can be expanded.

### Fourth Embodiment

Next, a motor drive device 1 according to the fourth embodiment of the present invention will be explained by referencing FIG. 5. The motor drive device 1 according to the fourth embodiment differs from the third embodiment in the point of the branch part 44 being a member further having thermal conductivity, and being arranged proximately to a separate element (peripheral element 30) that is arranged around the heat generating element 20, as shown in FIG. 5.

The branch part 44 is formed to be curved as appropriate in order to approach the peripheral element 30 to be cooled. Then, the branch part 44 is arranged in state in which a part of the outer face contacts the peripheral element 30 to be cooled.

Next, the cooling operation for the heat generating element 20, peripheral element 30 and distal element 60, using the heat sink 40 and fan motor 50, will be explained. By the cooling airflow F1 flowing through the air duct 43, the atmosphere of the surroundings of the main body 41 becomes positive pressure. In addition, the atmosphere within the air duct 43 becomes negative pressure. Moreover, the atmosphere inside of the branch part 44 becomes negative pressure. The flow F3 of air flowing into the other end of the branch part 44 is thereby formed at the surroundings of the other end of the branch part 44. Then, the inflowing air flows through the air duct 43 via the inside of the branch part 44. In addition, since the inside diameter and outside diameter of the other end part of the branch part 44 expand in diameter, a wider range of the flow of air is formed compared to the case of not expanding in diameter.

In addition, the branch part 44 exchanges heat with the peripheral element 30 arranged around the heat generating element 20. A flow F4 of heat carrying the heat which was exchanged with the peripheral element 30 to the heat sink 40 is formed on the outer circumferential part of the branch part 44.

According to the motor drive device 1 related to the above fourth embodiment of the present invention, the following such effects are exerted.

(4) The branch part 44 is formed from material having thermal conductivity, and is arranged proximately to a separate element (peripheral element 30) arranged around the heat generating element 20. The branch part 44 having thermal conductivity is in close contact with an element other than the heat generating element 20. By the element other than the heat generating element 20 and the branch part 44 exchanging heat, it is possible to also effectively cool elements other than the heat generating element 20.

The respective preferred embodiments of the motor drive device of the present invention have been explained above. The present invention is not to be limited to the aforementioned embodiments, and can be modified where appropriate. Modifications and improvements within a scope capable of achieving the object of the present invention are encompassed by the present invention. For example, the number of communication holes 42 was explained as three in the above-mentioned embodiments; however, it is not limited thereto. In other words, two or less, or four or more of the communication holes 42 may be provided. In addition, the communication holes 42 may be provided at appropriate positions in the main body 41 to match the installation positions of peripheral elements 30 to be cooled.

In addition, in the above-mentioned embodiments, the fan motor 50 of a form that discharges heat to the outside has been explained. In contrast, the fan motor 50 may be configured conversely so as to draw in air from the outside. Since it is thereby possible to make the inside of the motor drive device 1 to be positive pressure, it is possible to suppress debris, dust, etc. from entering the inside of the motor drive device 1 (inside of housing (not illustrated)) from a location other than the fan motor 50. In addition, the number of fan motors 50 is not limited to one, and a plurality thereof may be provided.

Moreover, the air duct 43 has been explained as being arranged to run vertically upwards in the above-mentioned embodiments; however, it is not limited thereto. For example, it is possible to adopt arranging to run along various directions, such as arranging the air duct 43 transversely.

In addition, in the above-mentioned third embodiment and fourth embodiment, the branch part 44 may be sloped so as to have the other end part approach the printed substrate 10, as shown in FIG. 6. The branch part 44 is thereby arranged to have the other end side approach the printed substrate 10 closer than the one side part. Therefore, the heated air is more abundantly flowed from the other end side of the branch part 44 to the one end side, by the convection of air. Therefore, the flow of air around the other end part of the branch part 44 further increases, and it is possible to more efficiently cool the distal element 60.

In addition, in the above-mentioned third embodiment, the branch part 44 may be arranged to curve in order to avoid interference with the peripheral element 30.

In addition, in the above-mentioned fourth embodiment, the branch part 44 may contact with the peripheral device via a thermally conductive material such as thermally conductive grease (not illustrated). It is thereby possible to improve the cooling efficiency (heat-exchange efficiency) of the peripheral element 30, eliminating the air layer between the outer face of the branch part 44 and the outer face of the peripheral device.

In addition, it is possible to establish the branch part 44 as a cylindrical heat pipe in the above-mentioned fourth embodiment. For example, the branch part 44 includes a fluid layer (not illustrated) at the inside of a wall part demarcating the inner circumferential face and outer circumferential face. A heat-exchange fluid having high thermal conductivity (not illustrated) is enclosed in this fluid layer (not illustrated). The heat-exchange fluid changes phases from liquid to gas by exchanging heat with the peripheral element 30, and then migrates to one end side of the branch part 44. The heat-exchange fluid returns to the liquid phase at the one end side of the branch part 44, and then migrates to the other end side of the branch part 44.

### EXPLANATION OF REFERENCE NUMERALS

1 motor drive device
10 printed substrate
20 heat generating element
30 peripheral element
40 heat sink
41 main body
42 communication hole
43 air duct
44 branch part
50 fan motor
F1 cooling airflow

What is claimed is:

1. A motor drive device comprising:
a heat sink that cools a heat generating element on a printed substrate by exchanging heat with the heat generating element; and a fan motor,
wherein the heat sink includes: a main body, of cylindrical shape, arranged adjacently to the heat generating element, and having an air duct through which cooling airflow flows; and a communication hole that communicates from an exposed outer circumferential face of the main body to the air duct, and
wherein the fan motor generates cooling airflow that flows through the air duct.

2. The motor drive device according to claim 1, wherein the communication hole communicates from the outer circumferential face of the main body to the air duct by sloping to a downstream side of the cooling airflow.

3. The motor drive device according to claim 1, further comprising a branch part of cylindrical shape that projects from the outer circumferential face of the main body, and communicates with the air duct via the communication hole.

4. The motor drive device according to claim 3, wherein the branch part is a member having thermal conductivity, and is arranged proximately to a separate element which is arranged around the heat generating element.
